(19) United States
(12) Patent Application Publication
(10) Pub. No.: US 2007/0111340 A1
(43) Pub. Date: May 17, 2007

(54) Method for in-line testing of semiconductor wafers

(75) Inventor: Itzik Goldberger, Lafayette, CA (US)

Correspondence Address: SUGHRUE MION, PLLC, 2100 PENNSYLVANIA AVENUE, N.W., SUITE 800, WASHINGTON, DC, 20037, US

(73) Assignee: CREDENCE SYSTEMS CORPORATION, Milpitas, CA (US)

(21) Appl. No.: 11/345,096

(22) Filed: Jan. 31, 2006

Related U.S. Application Data
(60) Provisional application No. 60/737,238, filed on Nov. 15, 2005.

(51) Int. Cl. H01L 21/66

(52) U.S. Cl. 438/17; 438/18

(57) ABSTRACT

A test circuit is fabricated in the device layer of the wafer. Metal contact is made between the test circuit and at least one metal layer, e.g., M2. The normal metal line fabrication process, e.g. Damascene process, is performed to fabricate contacts and pattern the trenches of the metal lines. After the metal layer of the contact layer, e.g., M2 is provided over the wafer to cover the trenches, the metal layer is contacted by the probe to send test signals to the test circuit. The electrical response characteristics can then be observed. After the testing, CMP of the metal layer is performed in the normal process of patterning the trenches, thereby removing any potential contamination introduced during the electrical testing.

### CROSS-REFERENCE TO RELATED APPLICATION

This application claims the benefit of priority from Provisional Patent Application No. 60/737,238 filed on Nov. 15, 2005, the entire disclosure of which is relied upon and incorporated by reference herein.

### BACKGROUND

1. Field of the Invention

The present invention relates to an apparatus and method for probing semiconductor wafers during work in progress (WIP).

2. Description of the Related Art

Semiconductor chips are generally fabricated using semiconductor wafers having silicon as a substrate and adding various materials onto, and removing materials from, the silicon substrate. The general structure is depicted in FIG. 1, wherein a device layer 110 is formed in substrate 100 using various known techniques, such as ion implantation, deposition, etch, etc. The device layer generally comprises many transistors, such as CMOS transistors. The device layer fabrication is generally referred to in the industry as front-end fabrication. Once the front-end fabrication is completed, an insulation layer 115 is formed over the device layer and the backend fabrication commences. In the backend fabrication, alternating conductive and insulating layers are formed to provide several layers, of wire mesh, here M1 to M5, that connects various transistors into logical elements so as to form various electrical circuits, which provide the functionality of the chip itself. As is known in the industry, the wires are formed in two perpendicular directions, generally referred to as Manhattan structure. However, due to the two dimensionality of the drawing, in FIG. 1 only one direction of wires is shown—the other direction being into the page. Also shown in FIG. 1 are the various contacts 125 that provide the electrical connections between the metal lines and the active devices.

According to the current technology, a metal layer is fabricated by the following general method (while variations exist in the industry, e.g., via-first, trench-first dual damascene, etc., for the purpose of this invention the following generic process is used throughout this specification to encompass all variations of the damascene process). First, the circuitry that is to be formed by the metal lines and contact holes is etched into the insulating layer 115. Then, the entire wafer is covered with metal, generally copper, which also enters the etched lines 145 and contact holes 125 made in the insulating layer 115. Then, a process known as chemical-mechanical planarization (CMP) is used to remove the top layer of the metal so as to expose the top section of the insulating layer. Consequently, while the metal layer is removed from the top surface of the wafer, the metal that enters the etched lines and contact holes in the insulating layer 115 remains. This process is similar to the process used by sword makers in ancient Damascus, Syria, to inscribe their name on the sword, and is therefore conventionally referred to as Damascene. A cross section A-A in FIG. 1 shows the contact hole 125′ and metal line 145′ filled with metal. The broken-line layer 155′ indicates the excess metal that is first layered on the entire wafer, but is then removed by CMP so that another insulating layer 135″ can be formed over the metal line 145′.

As is well known, semiconductor fabrication is done in a clean room using highly automated systems so as to avoid any possible contamination of the wafers. Also, due to the complexity of the fabrication process, each semiconductor wafer undergoes many measurements to ensure that processing is done according to specification and that the yield of properly functioning devices is as high as possible. However, to avoid contaminating the wafer, most measurements done during the fabrication process (WIP) are performed without contacting the wafer. Consequently, conventional measurements are limited to using light and e-beam optics to measure various physical dimensions of fabricated structures on the wafers. Such measurements provide, for example, layer thickness, critical dimension (CD), etc. These measurements are then used to deduce the electrical functionality of the chip being fabricated, using theoretical calculations, modeling, various experiments, etc.

While providing physical measurements of various structures is important, what is of utmost interest is the electrical functionality of the chip being fabricated. Dynamic electrical testing, i.e., application of time-varying voltage to the active devices, is the ultimate test for the functionality of the tested devices. Such test can point to defects in the design and/or fabrication of the chip so that remedial measures can be taken. Various testers are available in the art for testing electrical functionality of chips, however, such testers require contacting a metal contact point so that a test signal can be transmitted into the chip. Since contacting the wafer is certain to lead to contamination, in the prior art these testers are not used until the final metal layer is fabricated and a passivation insulating layer 135 is fabricated to protect the chip from the environment. At this point, the tester probes can be contacted to the pads that are provided on the chip so as to transmit the test signals. One system for performing dynamic testing of wafer is disclosed in U.S. Pat. No. 6,859,031, which is assigned to the current assignee and is incorporated herein in its entirety.

Another art for electrical testing uses DC, or static, based electrical test, which is done during manufacturing. According to this art, independent test structures are formed on areas that are outside of the die area of the chip. Conventionally these static test devices are formed on the scribe lines, so that they are electrically and physically separated from the chip's active circuitry. These conventional static tests use a DC signal to investigate the response of the test structure itself to the static stimulus. An example for such as static test is a threshold voltage test, wherein a static potential is applied to the test structure to measure the voltage level at which transistors changes state. The response of the test device is well correlated to the behavior of the active area devices. However, as fabrication technology advances it becomes very difficult to correlate the response characteristics of the static test structure to the response and performance of the devices forming the circuitry of the chip itself. Consequently, in the current art static testing is losing it's effectiveness as a leading indicator for yield problems, due to the large variability in advanced process, and thin design marginalities.

Generally, back end fabrication costs are higher than front end. Therefore, if a problem can be identified early during the backend processing, much resource can be saved. For example, current generation devices have 7-9 metal layers. However, the fabrication cost incurred after completion of the second metal layer, M2, can amount up to 60% of the total cost of fabricating the chip. Therefore, if a problem can be identified at the M2 layer, further fabrication can be stopped to avoid wastefully fabricating the remaining layers.

The reason layer M2 is important is that once fabrication of M2 is completed, every transistor on the substrate is connected to a metal line. Therefore, if one can somehow define the electrical circuitry and send a signal to M2, one can activate the transistors and test their response characteristics. However, heretofore no dynamic (AC) electrical testing of the chip at the M2 fabrication step is performed. One reason for that is fear of contamination. One proposal for performing electrical testing during wafer fabrication is disclosed in U.S. Pat. No. 5,899,703. There, an entire process sequence is proposed for constructing contacts and metal layer that will be used for testing, and when testing is completed removed. While this proposal may enable electrical testing while avoiding contamination, it introduces many design and process steps that are expensive and may themselves cause defects in the IC. For example, fabrication and removal of metal contacts may lead to introduction of shorts or changes in resistive characteristics of the contacted devices.

### SUMMARY

Various embodiments of the present invention provide apparatus and method for electrical testing of semiconductor wafers during WIP.

In one aspect of the invention, a test circuit is fabricated in the device layer of the wafer. The test circuit is formed in the active area of the chip itself. Metal contact is made between the test circuit and one or more metal layer, e.g., M2 and M1. After the metal layer of the contact layer, e.g., M2 is deposited over the wafer, but before the CMP process is completed to form the various metal lines, the metal layer is contacted by the probe to send test signals to the test circuit. The electrical response characteristics can then be observed. After the testing, CMP of the metal layer is performed, thereby removing any potential contamination introduced during the electrical testing.

In one aspect of the invention, the test circuit is independent of the chip circuitry and the dynamic testing is performed on the test circuitry only. According to another aspect of the invention, the test circuitry is connected to the various elements of the chip circuitry and, when voltage signal is applied to the test circuitry, the test circuitry activates various devices of the chip itself so that the response of chip devices can be studied. According to yet another aspect, no test circuit is formed. Rather the test signals are applied to the chip transistors themselves by contacting the metal layers.

Using dynamic testing for analysis is superior to static testing since it provides more information regarding the device's performance. Additionally, certain problems may not show up unless the chip is operating under time-varying conditions, which is the natural operating environment of the chip. Conventionally, chips are rated at various clock speeds. However, static tests cannot provide information as to the chip's functionality at the rated clock speed. On the other hand, the dynamic test can be set at the same clock speed as the chip's rating, and the chips functionality at that speed can be investigated.

In one embodiment of the invention, a method is provided for testing an integrated circuit during fabrication of a semiconductor wafer, the integrated circuit comprising a substrate, a device layer formed on the substrate, a plurality of interconnect layers, and a plurality of insulation layers each formed under respective one of the interconnect layers, the method comprising: a) fabricating a test circuitry in said device layer; b) fabricating electrical connections to form electrical contact between said testing circuitry to at least one of said interconnect layers; c) fabricating one of said interconnect layers by coating layer of conductive material over a respective insulation layer, to thereby form a metal coat layer that electrically contacts said electrical connections; d) contacting said metal coat layer with a test probe; e) applying stimulus test signals to said test probe to thereby send the stimulus test signals to said test circuitry; and f) once testing is completed, removing said metal coat layer. This method may further include step c1 after step c, step c1 comprising patterning said metal coat layer. In this method, step b may comprise fabricating device electrical connections to form electrical contacts between active devices of said integrated circuit and said interconnect layer. In this method, the coating of step c may comprise applying a layer of copper on the entire top surface of said wafer. In this method, step f may comprise performing a chemical-mechanical planarization to remove said metal coat layer. In this method, the coating of step c may comprise electroplating said wafer with copper. In this method, step e may further comprise applying ground potential to the backside of said wafer. In this method, the wafer may comprise a plurality of dies, and wherein step a comprises fabricating a test circuitry in each one of said dies. In this method, step e may comprise applying stimulus test signals having time-varying voltage. In this method, step b may further comprise fabricating electrical connections to form electrical contact between said testing circuitry and selected devices of said integrated circuit.

In another embodiment of the invention, a method is provided for testing an integrated circuit during fabrication of a semiconductor wafer, the integrated circuit comprising a substrate, a device layer formed on the substrate, a plurality of interconnect layers, and a plurality of insulation layers each formed under respective one of the interconnect layers, the method comprising: a) fabricating a plurality of active devices to define said device layer; b) fabricating electrical connections to form electrical contact between selected ones of said plurality of active devices to at least one of said interconnect layers; c) fabricating one of said interconnect layers by coating layer of conductive material over a respective insulation layer, to thereby form a metal coat layer that electrically contacts said electrical connections; d) contacting said metal coat layer with a testing probe; e) applying stimulus test signals to said testing probe to thereby send the stimulus test signals to said selected ones of said plurality of devices; and f) once testing is completed, removing said metal coat layer. This method may further comprise step c1 after step c, said step c1 comprising patterning said metal coat layer. In this method, step a may further comprise fabricating test devices defining a test circuit within said integrated circuit. In this method, step b may further comprise fabricating electrical connections to form electrical contact between selected test devices and selected active devices. In this method, the coating of step c may comprise applying a layer of copper on the entire top surface of said wafer. In this method, step f may comprise performing a chemical-mechanical planarization to remove said metal coat layer. In this method, the coating of step c may comprise electroplating said wafer with copper. In this method, step e may further comprise applying ground potential to the backside of said wafer. In this method, the wafer comprises a plurality of dies, and wherein step a may comprise fabricating a test circuitry in each one of said dies. In this method, step e may comprise applying stimulus test signals having time-varying voltage.

In yet another embodiment of the invention, a method is provided for testing an integrated circuit during fabrication of a semiconductor wafer, the integrated circuit comprising a substrate, a device layer formed on the substrate, a plurality of interconnect layers, and a plurality of insulation layers each formed under respective one of the interconnect layers, the method comprising: a) fabricating a plurality of active devices to define said device layer; b) fabricating electrical connections to form electrical contact between selected ones of said plurality of active devices to at least one of said interconnect layers; c) fabricating one of said interconnect layers by coating layer of conductive material over a respective insulation layer, to thereby form a metal coat layer that electrically contacts said electrical connections; d) contacting said metal coat layer with a testing probe; e) applying dynamic stimulus test signals having time-varying voltage to said testing probe to thereby send the dynamic stimulus test signals to said selected ones of said plurality of devices; and f) once testing is completed, removing said metal coat layer. In this method, step a may further comprise fabricating test devices defining a test circuit within said integrated circuit. In this method, step b may further comprise fabricating electrical connections to form electrical contact between selected test devices and selected active devices. This method may further comprises step c1 after step c, said step c1 comprising patterning said metal coat layer. In this method, step e may further comprise applying ground potential to the backside of said wafer. In this method, the coating of step c may comprise applying a layer of copper on the entire top surface of said wafer.

The disclosed and claimed invention is especially beneficial since a standard damascene fabrication process is used, so that no additional process is needed for fabrication and removal of a contact layer. Rather, the contacts that are formed in conventional damascene process are used.

Other aspects and features of the invention will become apparent from the description of various embodiments described herein, and which come within the scope and spirit of the invention as claimed in the appended claims.

### BRIEF DESCRIPTION OF THE DRAWINGS

FIGS. 1 is a general schematic depicting wafer fabrication according to the prior art.

FIGS. 2A and 2B depict an embodiment of the subject invention.

FIG. 3 is a flow chart of a process according to an embodiment of the subject invention.

FIGS. 4A and 4B depict another embodiment of the invention.

FIG. 5 is a flow chart depicting an embodiment for a method according to the present invention.

FIG. 6 depicts yet another embodiment of the subject invention wherein the test circuitry is connected to the chip's circuitry.

FIG. 7 depicts another embodiment of the subject invention wherein no test circuits are provided.

FIGS. 8a-8c depict general process flow of conventional Damascene process, while FIGS. 9a-9d depict general schematic of Damascene process according to an embodiment of the invention.

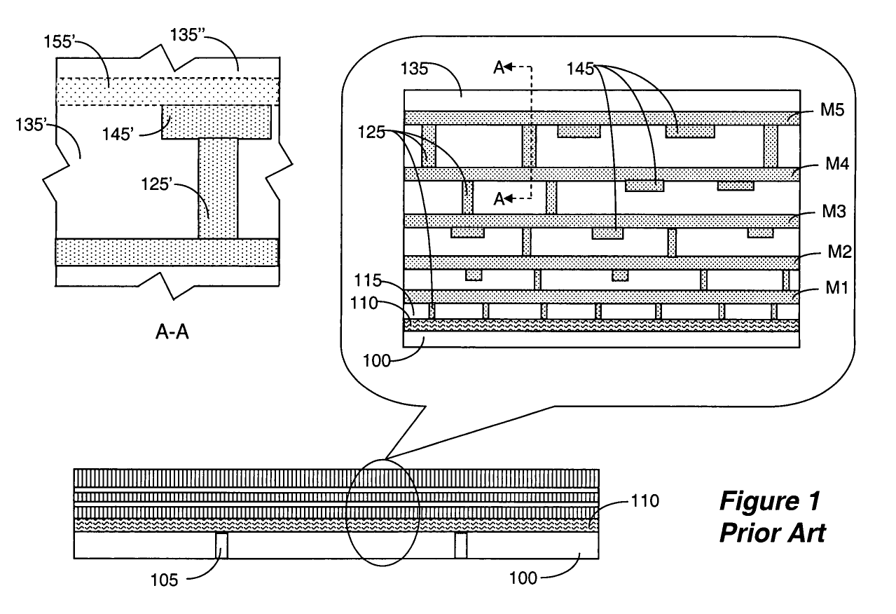

The invention is described herein with reference to particular embodiments thereof, which are exemplified in the drawings. It should be understood, however, that the various embodiments depicted in the drawings are only exemplary and may not limit the invention as defined in the appended claims.

### DETAILED DESCRIPTION

Various embodiments of the present invention provide apparatus and method for dynamic electrical testing of wafers during the fabrication process (WIP). These embodiments enable electrical testing of wafers as early as, e.g., during the fabrication of the first or second metal line, M1 or M2. These embodiments enable dynamic electrical testing while avoiding any contamination of the wafer.

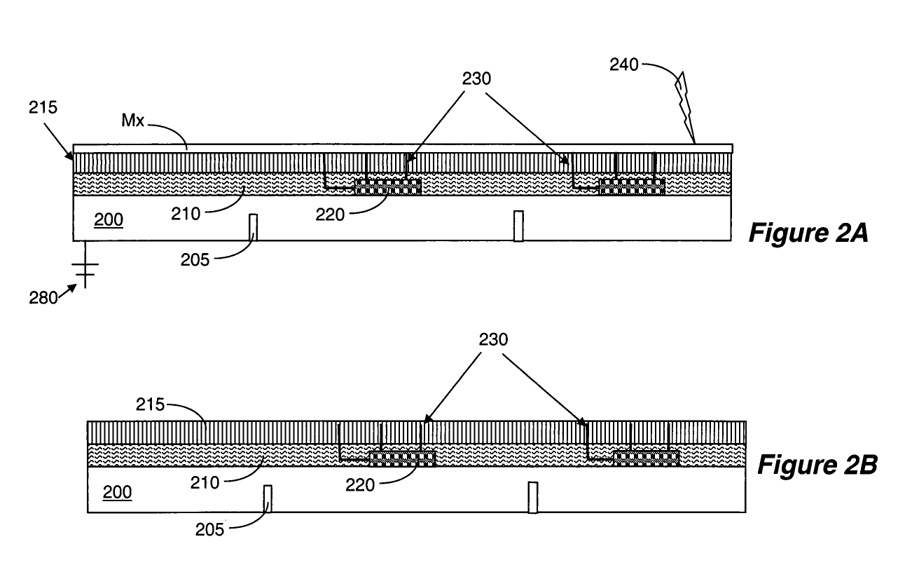

FIGS. 2A and 2B depict an embodiment of the subject invention. In FIGS. 2A and 2B, device layer 210 is fabricated in substrate 200 and is covered by insulating layer 215. Scribe lines 205 delineate the borders between the dies (chips) that are being fabricated on the wafer. FIG. 2A depicts the wafer at the step where it is covered with a metal layer, Mx, which may be, e.g., M1, M2, etc., while FIG. 2B depicts the wafer after the top metal covering has been removed by, e.g., CMP.

According to this embodiment of the invention, test circuits 220 are fabricated in the device layer and within the die area at the same time that the chip devices are fabricated. Test circuits 220 are designed to perform various electrical tests using very few test signals, e.g., power and ground signals, and a small number of logical signals. These circuits may be similar to or modeled after conventional DFT (Design for Test) structures. Electrical contacts 230 are fabricated to connect test circuits 220 to metal layer Mx. As shown in FIG. 2A, when the metal layer is formed over the entire wafer, electrical signal can be transmitted to the test circuit by using probe 240 to contact the metal layer Mx. Another voltage level, such as ground, 280, can be provided to the test circuit via the substrate itself, which is generally placed on a chuck. The probe 240 can be used to send electrical signals to the test circuit 220 and to sense various electrical responses of the chip. Such dynamic testing can provide information about the actual dynamic electrical performance of the chip, rather than just DC based response or physical measurements as is done in the prior art. The probe 240 can be used with conventional testing equipment or with specially designed equipment that utilizes a reduced set of test signals to accomplish the testing.

Once dynamic electrical testing is completed, the top metal layer Mx is removed by, e.g., CMP processing. Consequently, any contamination introduced by the probe 240 is removed by the CMP process. This is shown in FIG. 2B. Thereafter, the process for building the next metal layer is performed and, if necessary, another sequence of dynamic electrical testing can be performed in the same manner as described with respect to layer Mx.

As can be understood, test circuit 220 can be fabricated in each die, or centrally for all of the dies in the wafer. Also, the test circuit can be constructed so as to respond to test signals of various voltage levels. The test circuit is generally constructed of transistors that are fabricated at the same time the transistors of the chip itself are fabricated. Also, since the various transistors of the chip itself also have contact lines to the metal layer, the electrical response of these transistors can also be tested. Similarly the transistors in the device active area themselves can be tested using the same approach.

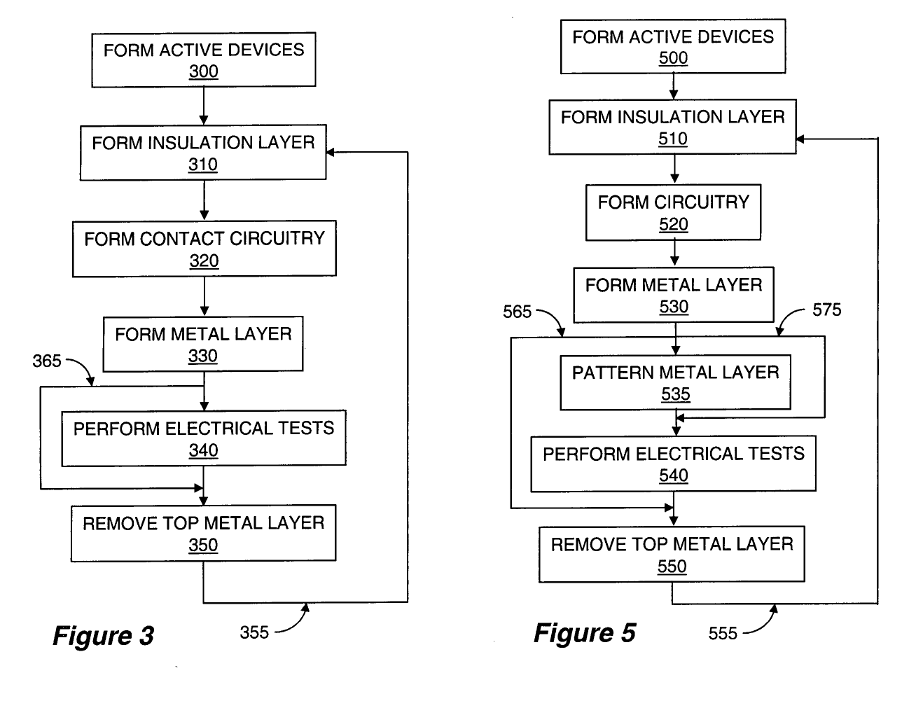

FIG. 3 is a flow chart of a process according to an embodiment of the subject invention. In step 300 the active devices, i.e., transistors are formed. These include the transistors that form the various circuits of the chip and the transistors that form the test circuit. In step 310 an insulation layer is formed (generally deposited) over the transistor layer. At step 320 the contact circuitry is formed. This step includes photolithography and etch steps to delineate contact holes (or vias) and metal lines in the insulation layer that was formed in step 310. In step 330 the entire wafer is covered with metal layer, generally copper. This is generally done using electroplating process. In step 340 dynamic electrical testing of the circuits is performed by using a probe to apply potentials to the metal layer formed in step 330. Once testing is completed, the metal layer is removed at step 350. The sequence is then repeated, as shown by arrow 355, so as to form the next metal layer. However, if no further dynamic electrical testing is needed, step 340 can be skipped, as shown by arrow 365.

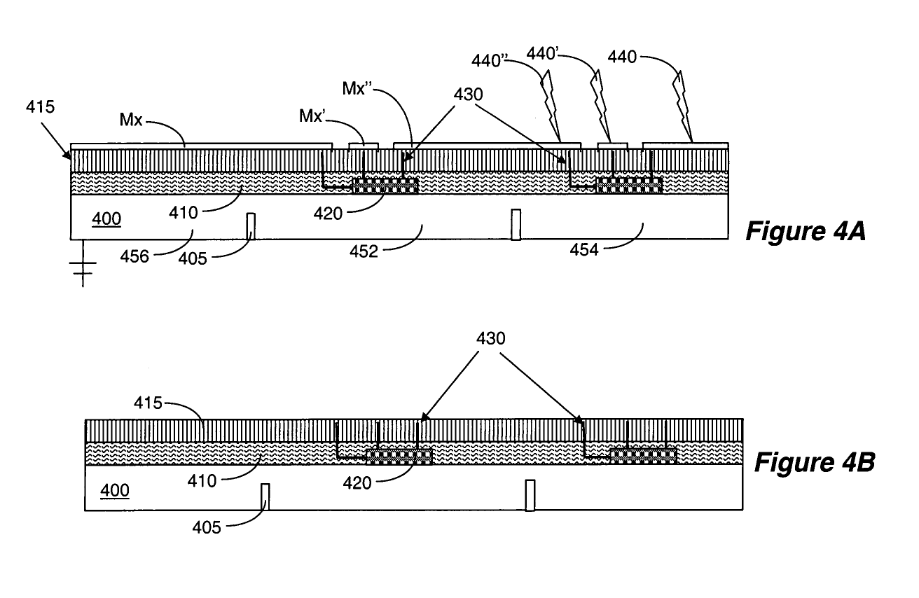

FIGS. 4A and 4B depict another embodiment of the invention. This embodiment is somewhat similar to that of FIGS. 2A and 2B, except that the metal layer Mx is patterned prior to the testing of the wafer. This enables the application of various test signals at various levels and to various parts of the test circuit or the devices of the chip itself. More specifically, as shown in FIG. 4A, the metal layer Mx is patterned, so that different contact lines 430 are electrically coupled to different sections of the metal layer, e.g., Mx, Mx′, Mx″ etc. The testing is accomplished by the probe 440 contacting different locations, i.e., Mx, Mx′, Mx″, or by using multiple probes on a probe card, 440, 440′, 440″. Each contacting different section of the metal layer Mx, Mx′, Mx″, etc.

The embodiment of FIGS. 4A and 4B can be practiced even when the metal layer is made of copper. While the Damascene technology has been developed in order to avoid patterning copper by, e.g., using etch technology, various methods for etching coppers have been developed. The main reason the industry avoids etching copper is for fear of contamination—copper is not volatile. Consequently, whenever copper is etched, copper residue remains in the etch chamber and can contaminate the next wafer entering the etch chamber. However, for the inventive embodiment of FIGS. 4A and 4B this is not an impediment. That is, as shown in FIG. 4B, once the testing is completed the entire top layer is removed by, e.g., CMP process. Therefore, any copper contamination introduced in the etch chamber to the top layer of the wafer will be removed during the CMP process.

FIG. 4A also exemplifies another feature of the invention. That is, while the discussion above relates to having a testing circuit inside a die or on the scribe lines, another option is to have one or more dies in the wafer being test dies, while the remaining dies be normal product dies. For example, dies 452 and 454 can be test dies, i.e., dies designed and fabricated specifically for testing, while die 456 is a normal product die. Therefore, the metal layer Mx over die 456 is shown as not patterned. Of course, if one wishes to also test devices in the normal device die 456, then the metal layer over die 456 can be patterned as well. Also, as shown in FIG. 4A, more than one die can be probed at one time. For example, probe 440″ is shown contacting metal section Mx″, which is connected to both die 454 and 452, thereby providing electrical contact to two dies. On the other hand, the probe can be constructed so that is contacts metal layers over several dies simultaneously.

FIG. 5 is a flow chart depicting an embodiment for a method according to the present invention. In step 500, the active devices of the chip and of the test circuit are formed on the substrate. Then, an insulation layer is formed on top of the devices in step 510. In step 520 circuitry is formed, i.e., contacts for electrically contacting various regions of the active elements are formed using, e.g., conventional patterning and fabrication techniques, such as, e.g., SAC (self aligned contact), etc. Also, trenches are formed in the insulation layer so as to form metal lines once metal is flowed into these trenches. The trenches are also made using conventional patterning technology such as, e.g., Damascene. The entire wafer is then coated with metal layer in step 530. In current technology the metal layer is generally copper that is electroplated over a seed layer and, optionally, a barrier layer.

Unlike the method of FIG. 3, here at step 535 the metal layer is patterned using, e.g., photolithography and metal etch process. The metal layer is patterned in such manner so as to have different contacts of the test circuit connected to different parts of the remaining metal layer. In this manner, different signals can be sent to different devices of the test circuit and/or the chip itself, and different sensors can be contacted to the various metal sections to sense different activities within the chip or the test circuit. This is done at step 540. Once testing is completed, the top layer is removed at step 550, using, e.g., CMP process. The sequence then can repeat itself from step 510 to step 550, as shown by arrow 555. However, if for any particular metal layer no testing is necessary, metal patterning and electrical testing steps can be skipped, as shown by arrow 565. Furthermore, if for any metal layer it is determined that testing can be done without the need to pattern the metal layer, step 535 can be skipped, as shown by arrow 575.

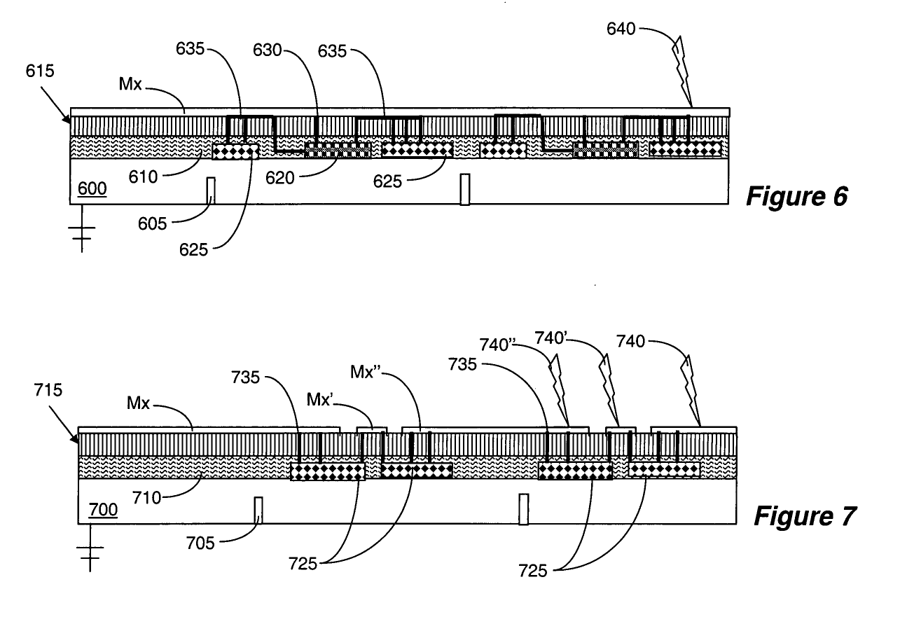

FIG. 6 depicts yet another embodiment of the subject invention wherein the test circuitry is connected to the chip's circuitry. This embodiment is somewhat similar to that of FIGS. 2A and 2B, except that the test circuits have electrical connections to various devices of the chip's circuit. This is schematically illustrated by contact lines 635 which make electrical connections between the test circuit 620 and various chip circuits 625. In this manner, when test signals are applied to the test circuit 620, the test circuit activates various devices of the chip circuit 625 via contacts 635. In this manner, dynamic testing of devices belonging to the chip circuitry can be performed. Such tests are particularly beneficial as the performance of the chip's devices can be tested directly. In FIG. 6 metal layer is shown as a single unpatterned layer. However, it should be understood that the metal layer may be patterned so as to form metal layer segments Mx, Mx′, and Mx″, as shown with respect to the embodiment of FIG. 4.

FIG. 7 depicts another embodiment of the subject invention wherein no test circuits are provided. This embodiment is rather different from the previous embodiments as here no test circuits are provided. Instead, various devices from the chip circuit, 725, itself are electrically connected via contacts 735 to the metal layer Mx. When dynamic test signals are applied to the metal layer Mx, the signal propagates along lines 735 and activate the related devices in chip circuit 725, so that the dynamic response of the devices can be tested directly. In FIG. 7 metal layer is shown as patterned so as to form metal layer segments, i.e., test pads, Mx, Mx′, and Mx″. However, it should be understood that the metal layer need not be patterned.

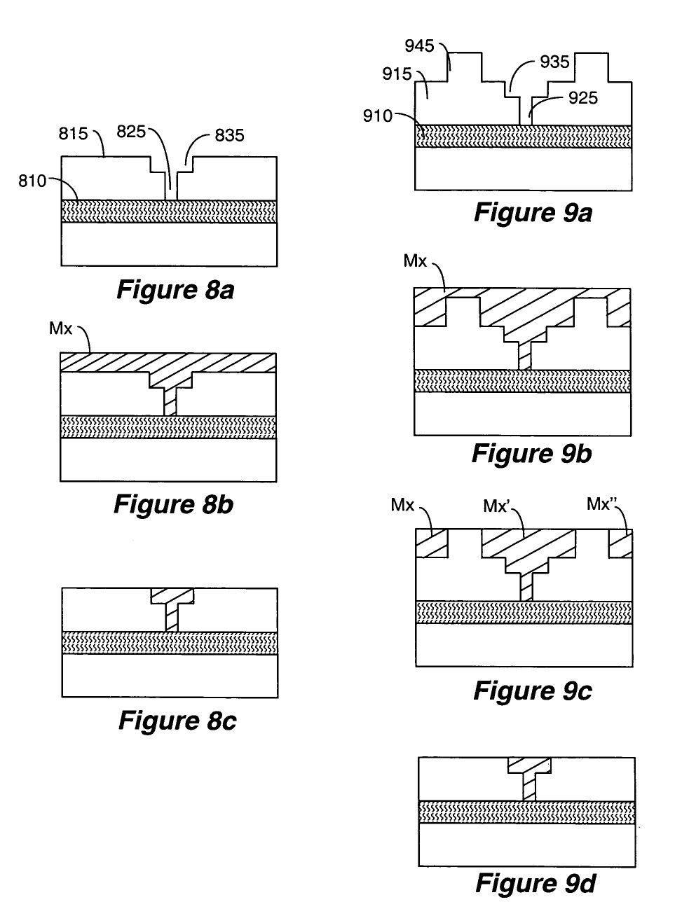

While patterning of the metal layer so as to provide various different voltages to different sections of the DUT can be made using any technique, another example is provided herein in addition to the etching described above. FIGS. 8a-8c depict general process flow of conventional Damascene process, while FIGS. 9a-9d depict general schematic of Damascene process according to an embodiment of the invention. While the Damascene process is well known in the art, for completeness a brief description of the process is provided with respect to FIGS. 8a-8c. Generally, once fabrication of the device layer 810 is complete, a layer 815 of an insulating material is deposited over the device layer. This layer may be made of any conventional dielectric material. Then, patterning of the contacts and trenches is made using conventional photolithography and etch technique. Conventionally, various techniques for the patterning are known, such as those referred to in the art as via first or trench first. However, for simplicity, the description proceeds here showing both the via 825 and trench 835 etched into the dielectric. Then, in FIG. 8b, the entire wafer is covered with a conductive material so as to form a metal layer Mx. As can be understood, since the description here refers to the first metal layer over the device layer, this is metal layer M1; however, the process described here may be repeated for any metal layer. The wafer is then processed in a CMP system so as to remove the top layer of the metal, Mx, resulting in the structure shown in FIG. 8c, wherein the metal remains only inside the via and trench.

According to an embodiment of the invention, the conventional Damascene process is modified to enable dynamic testing during wafer fabrication. As shown in FIG. 9a, the device layer 910 is covered with a dielectric layer 915 in a similar manner as in the prior art. Here, however, it would be advantageous to form the dielectric layer 915 thicker than conventional. The via 925 and trench 935 are then patterned in the dielectric layer 915; however, in addition, dielectric islands 945 are also patterned in the dielectric layer 915. Then, the entire wafer is covered with conductive material to form a metal layer Mx, as shown in FIG. 9b. The wafer is then processed in a CMP system so as to remove the metal layer Mx, but only up to the point where the top surface of the dielectric islands 945 is reached, as shown in FIG. 9c. At this stage, the metal layer is divided into conductive sections Mx′, Mx″, Mx′″, that are insulated from each other by dielectric islands 945. In this manner, sections Mx′, Mx″, and Mx′″ can serve as probe pads, allowing different voltages to be applied to different areas of the DUT for performing the testing. Of course, since conductive section Mx″ is electrically connected to via 925, it can be used to apply potential to transistors in device layer 910.

Once testing is completed, the wafer is again processed in the CMP system to remove the metal layer together with the dielectric islands, so that the conventional Damascene structure is obtained, as shown in FIG. 9d. Consequently, any contamination caused during the testing is removed during the second Damascene process.

While the invention has been described with reference to particular embodiments thereof, it is not limited to those embodiments. Specifically, various variations and modifications may be implemented by those of ordinary skill in the art without departing from the invention's spirit and scope, as defined by the appended claims. Additionally, all of the above-cited prior art references are incorporated herein by reference.

What is claimed is:

1. A method for electrical testing of devices during fabrication of an integrated circuit, the integrated circuit comprising a wafer substrate, a device layer formed in the substrate, a plurality of interconnect layers, and a plurality of insulation layers each formed under respective one of the interconnect layers, the method comprising:
a. fabricating a test circuitry in said device layer;
b. fabricating electrical connections to form electrical contact between said testing circuitry to at least one of said interconnect layers;
c. fabricating one of said interconnect layers by coating layer of conductive material over a respective insulation layer, to thereby form a metal lines layer in said respective insulation layer so as to electrically contact said electrical connections, and a metal coat layer over said insulation layer;
d. contacting said metal coat layer with a test probe;
e. applying stimulus test signals to said test probe to thereby send the stimulus test signals to said test circuitry;
f. once testing is completed, removing said metal coat layer so as to expose said respective insulation layer and metal lines layer; and,
g. forming a successive insulation layer over said respective insulation layer and metal lines layer.

2. The method of claim 1, further comprising step c1 after step c, said step c1 comprising patterning said metal coat layer.

3. The method of claim 2, wherein said patterning comprises using photolithography to delineate patterns over said metal coat layer and etching parts of said metal coat layer according to said patterns.

4. The method of claim 2, wherein said patterning comprises etching metal lines circuitry in said respective insulation layer, and etching dielectric islands in said respective insulation layer above said metal lines circuitry, and wherein step f further comprises removing said dielectric islands.

5. The method of claim 1, wherein step b further comprises fabricating device electrical connections to form electrical contacts between active devices of said integrated circuit and said interconnect layer.

6. The method of claim 1, wherein said coating of step c comprises applying a layer of copper on the entire top surface of said wafer.

7. The method of claim 6, wherein step f comprises performing a chemical-mechanical planarization to remove said metal coat layer.

8. The method of claim 6, wherein said coating of step c comprises electroplating said wafer with copper.

9. The method of claim 1, wherein step e further comprises applying ground potential to the backside of said wafer.

10. The method of claim 1, wherein said wafer comprises a plurality of dies, and wherein step a comprises fabricating a test circuitry in each one of said dies.

11. The method of claim 1, wherein step e comprises applying stimulus test signals having time-varying voltage.

12. The method of claim 1, wherein step b further comprises fabricating electrical connections to form electrical contact between said testing circuitry and selected devices of said integrated circuit.

13. A method for electrically testing devices during fabrication of an integrated circuit, the integrated circuit comprising a wafer substrate, a device layer formed in the substrate, a plurality of interconnect layers, and a plurality of insulation layers each formed under respective one of the interconnect layers, the method comprising:
a. fabricating a plurality of active devices to define said device layer;
b. fabricating electrical connections to form electrical contact between selected ones of said plurality of active devices to at least one of said interconnect layers;
c. fabricating one of said interconnect layers by coating layer of conductive material over a respective insulation layer, to thereby form a metal lines layer in said respective insulation layer so as to electrically contact said electrical connections, and a metal coat layer over said insulation layer;
d. contacting said metal coat layer with a testing probe;
e. applying stimulus test signals to said testing probe to thereby send the stimulus test signals to said selected ones of said plurality of devices;
f. once testing is completed, removing said metal coat layer so as to expose said respective insulation layer and metal lines layer; and,
g. forming a successive insulation layer over said respective insulation layer and metal lines layer.

14. The method of claim 13, further comprising step cl after step c, said step cl comprising patterning said metal coat layer.

15. The method of claim 14, wherein said patterning comprises using photolithography to delineate patterns over said metal coat layer and etching parts of said metal coat layer according to said patterns.

16. The method of claim 14, wherein said patterning comprises etching metal lines circuitry in said respective insulation layer, and etching dielectric islands in said respective insulation layer above said metal lines circuitry, and wherein step f further comprises removing said dielectric islands.

17. The method of claim 13, wherein step a further comprises fabricating test devices defining a test circuit within said integrated circuit.

18. The method of claim 17, wherein step b further comprises fabricating electrical connections to form electrical contact between selected test devices and selected active devices.

19. The method of claim 13, wherein said coating of step c comprises applying a layer of copper on the entire top surface of said wafer.

20. The method of claim 19, wherein step f comprises performing a chemical-mechanical planarization to remove said metal coat layer.

21. The method of claim 19, wherein said coating of step c comprises electroplating said wafer with copper.

22. The method of claim 13, wherein step e further comprises applying ground potential to the backside of said wafer.

23. The method of claim 17, wherein said wafer comprises a plurality of dies, and wherein step a comprises fabricating a test circuitry in each one of said dies.

24. The method of claim 13, wherein step e comprises applying stimulus test signals having time-varying voltage.

25. A method for electrically testing devices during fabrication of an integrated circuit, the integrated circuit comprising a wafer substrate, a device layer formed in the substrate, a plurality of interconnect layers, and a plurality of insulation layers each formed under respective one of the interconnect layers, the method comprising:
a. fabricating a plurality of active devices to define said device layer;
b. fabricating electrical connections to form electrical contact between selected ones of said plurality of active devices to at least one of said interconnect layers;
c. fabricating one of said interconnect layers by coating layer of conductive material over a respective insulation layer, to thereby form a metal lines layer in said respective insulation layer so as to electrically contact said electrical connections, and a metal coat layer over said insulation layer;
d. contacting said metal coat layer with a testing probe;
e. applying dynamic stimulus test signals having time-varying voltage to said testing probe to thereby send the dynamic stimulus test signals to said selected ones of said plurality of devices;
f. once testing is completed, removing said metal coat layer so as to expose said respective insulation layer and metal lines layer; and,
g. forming a successive insulation layer over said respective insulation layer and metal lines layer.

26. The method of claim 25, wherein step a further comprises fabricating test devices defining a test circuit within said integrated circuit.

27. The method of claim 26, wherein step b further comprises fabricating electrical connections to form electrical contact between selected test devices and selected active devices.

28. The method of claim 25, further comprising step c1 after step c, said step c1 comprising patterning said metal coat layer.

29. The method of claim 28, wherein said patterning comprises using photolithography to delineate patterns over said metal coat layer and etching parts of said metal coat layer according to said patterns.

30. The method of claim 28, wherein said patterning comprises etching metal lines circuitry in said respective insulation layer, and etching dielectric islands in said respective insulation layer above said metal lines circuitry, and wherein step f further comprises removing said dielectric islands.

31. The method of claim 28, wherein step e further comprises applying ground potential to the backside of said wafer.

32. The method of claim 31, wherein said coating of step c comprises applying a layer of copper on the entire top surface of said wafer.
